(19) United States
(12) Patent Application Publication
(10) Pub. No.: US 2009/0243659 A1
(43) Pub. Date: Oct. 1, 2009

(54) METHOD AND DEVICE FOR DETECTING THE ABSENCE OF A PERIODIC SIGNAL

(76) Inventors: Praveen MOSALIKANTI, Portland, OR (US); Nasser A. KURD, Portland, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 12/056,406

(22) Filed: Mar. 27, 2008

(51) Int. Cl. G01R 29/027; H04L 7/00

(52) U.S. Cl. 327/2; 375/358

(57) ABSTRACT

A method and device may determine the absence of a periodic signal or the absence of an edge of the periodic signal. The periodic signal may be a transmitted clock signal in a forwarded clock architecture. The periodic signal may be delayed by a fixed phase difference to produce a delayed periodic signal. The phase difference between the periodic signal and the delayed periodic signal may be determined. If the determined phase difference is above or below the fixed phase difference by a predetermined amount or more the periodic signal may be missing an edge. If the absence of the periodic signal or the absence of the edge of the periodic signal is detected, an error signal may be asserted. The error signal may be an in-band reset signal.

### BACKGROUND OF THE INVENTION

1. Field of the Invention

Embodiments of the present invention relate to a method and device operable to determine the absence of a periodic signal or the absence of an edge of the periodic signal. More specifically, embodiments of the present invention relate to a method and device operable to determine the absence of a periodic signal or the absence of an edge of the periodic signal in a forwarded clock architecture.

2. Description of the Related Art

A communication system may include at least one transmitter and at least one receiver. In a forwarded clock architecture, the transmitter transmits a clock signal with a data signal. The receiver uses the transmitted clock signal as the timing signal for the transmitted data signal. A forwarded clock architecture may be used, for example, when the timing signal is not embedded within the transmitted data signal.

If the transmitter stops transmitting the clock signal, the receiver needs to detect this loss of a clock signal. Once the loss of the clock signal is detected, in one scheme the receiver must assert a signal indicating the loss of the clock signal to logic circuits that rely on the transmitted clock signal being valid. This signal is typically referred to as an in-band reset signal. Detecting the loss of the transmitted clock signal and asserting the in-band reset signal need to be achieved while minimizing detection latency and the risk of metastability. Failure to do so could result in data corruption—e.g., from a late detection or from an incorrect assertion of the in-band reset signal.

Prior art techniques for detecting the loss of the transmitted clock include taking samples of the transmitted clock using a sampling clock of nominally identical frequency. Two samples are taken of every “clock high” portion of the clock signal (when the clock signal is at logic ‘1’) and every “clock low” portion of the clock signal (when the clock signal is at logic ‘0’). The sampling clock is generally a slightly delayed version of each edge of the transmitted clock. Under ideal conditions, the samples should be 00, 11, 00, 11, etc. If an edge of the transmitted clock signal is lost (e.g., the clock signal remains high or the clock signal remains low for at least one clock edge), the resultant samples would be at least four consecutive 0's or at least four consecutive 1's.

However, the prior art approach is not ideal. There is a risk of metastability on every edge of the transmitted clock due to sampling the transmitted clock with another completely different clock. Although the transmitted clock and the sampling clock are nominally at the same frequency, there is no defined phase difference between them. However, even if there is a defined phase difference between the clocks, it is difficult to accurately predict the amount of delay to use in creating the delayed samples. For example, there is a need to account for jitter on the transmitted clock, jitter on the sampling clock, skew between the clocks, duty cycle distortion, and differences between simulated and actual delays.

### BRIEF DESCRIPTION OF THE DRAWINGS

Embodiments of the invention will be understood and appreciated more fully from the following detailed description in conjunction with the figures, which are not to scale, in which like reference numerals indicate corresponding, analogous or similar elements, and in which:

FIG. 1 shows a communication system according to an embodiment of the present invention;

FIG. 2 shows a flowchart of a method for determining if a periodic signal is absent or if the periodic signal is missing an edge according to an embodiment of the present invention;

FIG. 3 shows a simplified block diagram of a Delay Locked Loop (DLL) implemented with analog circuit elements according to an embodiment of the present invention;

FIG. 4 shows a device which may be used to detect the absence of a periodic signal or the absence of an edge of the periodic signal according to an embodiment of the present invention;

FIG. 5 shows a timing diagram in which a rising edge of a periodic signal is lost according to an embodiment of the present invention; and

FIG. 6 shows a timing diagram in which a falling edge of a periodic signal is lost according to an embodiment of the present invention.

### DESCRIPTION OF THE PREFERRED EMBODIMENT

In the following detailed description, numerous specific details are set forth in order to provide a thorough understanding of the subject matter disclosed herein. However, it will be understood by those of ordinary skill in the art that embodiments of the present invention may be practiced without these specific details. In other instances, well-known methods, procedures, components and circuits have not been described in detail so as not to obscure embodiments of the present invention.

Unless specifically stated otherwise, as apparent from the following discussions, it is appreciated that throughout the specification, discussions utilizing terms such as “processing,” “computing,” “calculating,” “determining,” “comparing”, or the like, may refer to the action and/or processes of a processor, computer or computing system, or similar electronic computing device, that manipulates and/or transforms data represented as physical, such as electronic, quantities within the computing system's registers and/or memories into other data similarly represented as physical quantities within the computing system's memories, registers or other such information storage, transmission or display devices.

The processes and displays presented herein are not inherently related to any particular computer, communication device or other apparatus. Embodiments of the present invention are not described with reference to any particular programming language, machine code, or the like.

Embodiments of the present invention may include a computer program stored in a computer readable storage medium, such as, but is not limited to, any type of disk including floppy disks, optical disks, magnetic-optical disks, read-only memories, compact disc read-only memories, random access memories, electrically programmable read-only memories, electrically erasable and programmable read only memories, magnetic or optical cards, or any other type of media suitable for storing electronic instructions, and capable of being coupled to a computer system bus.

Embodiments of the present invention may include or use digital logic signals. These logic signals may be described as having a certain logic level, for example, logic ‘1’ or logic ‘0’. As is understood by those skilled in the art, this is done merely for illustrative purposes to clarify an embodiment of the invention and is not meant to indicate that only the indicated logic level is operable. For example, if a circuit has an input which is used to enable the circuit, the input signal may be described as being logic ‘1’ to enable the circuit and logic ‘0’ to disable the circuit. However, those skilled in the art will recognize that this is true only if the circuit's enable input is active-high. In another embodiment, the circuit's enable input may be active-low in which case a logic ‘0’ input will enable the circuit and a logic ‘1’ will disable the circuit. Because such alternatives are well-known by those of ordinary skill in the art, only a single embodiment may be described herein. However, other embodiments having different logic levels are considered a part of the present invention.

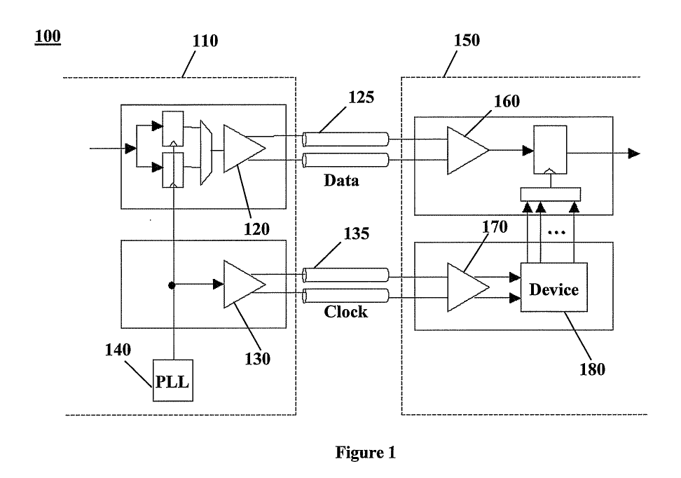

FIG. 1 shows a communication system 100 according to an embodiment of the present invention. The communication system includes a first apparatus 110. The first apparatus 110 may include, for example, a first transmitter 120 to transmit data 125 and a second transmitter 130 to transmit a periodic signal 135. The frequency and/or the phase of the periodic signal may be controlled by, for example, a Phase Locked Loop (PLL) 140. The periodic signal 135 may be a clocking signal and the data 125 may be clocked using the periodic signal. The communication system includes a second apparatus 150. The second apparatus 150 may include, for example, a first receiver 160 to receive the data from the first transmitter and a second receiver 170 to receive the periodic signal from the second transmitter. The second apparatus may include a device 180.

In embodiments of the present invention, the device 180 may comprise, for example, a delay circuit, a phase detector, a comparator, and/or an error asserter to detect the absence of a periodic signal or the absence of an edge of the periodic signal. An edge of a signal may occur, for example, when the signal transitions from a low (e.g., logic ‘0’) to a high (e.g., logic ‘1’) in which case the edge may be known as a “rising edge”. An edge of a signal may occur, for example, when the signal transitions from a high (e.g., logic ‘1’) to a low (e.g., logic ‘0’) in which case the edge may be known as a “falling edge”.

In embodiments of the present invention, the device 180 may comprise a delay circuit which may be capable of, for example, delaying the periodic signal by a fixed phase difference to produce a delayed periodic signal. A “phase difference” may be, for example, a measure of the delay between two periodic signals that have the same frequency but difference phases. If the frequency differs, the phase difference will change as a function of the frequency difference. Phase difference may be expressed in, for example, degrees or radians. To clarify, a sine wave [sin(x)] and a cosine wave [cos(x)] each having the same frequency have a phase difference of 90°. The delay circuit may be capable of maintaining the fixed phase difference between the periodic signal and the delayed periodic signal.

The device 180 may comprise a phase detector which may be capable of determining a phase difference between the periodic signal and the delayed periodic signal. When the periodic signal is present and is not missing an edge, the delay circuit may act to maintain the fixed phase difference between the periodic signal and the delayed periodic signal. Under these circumstances, the phase detector may detect that the difference between the determined phase difference and the fixed phase difference is substantially zero or is less than a predetermined amount. When the periodic signal is not present and/or is missing an edge, the delay circuit may be incapable of maintaining the fixed phase difference between the periodic signal and the delayed periodic signal. Under these circumstances, the phase detector may detect that the periodic signal and the delayed periodic signal are no longer delayed by the fixed phase difference. The phase detector may be capable of determining if the phase difference between the periodic signal and the delayed periodic signal is equal to, above, or below the fixed phase difference. The phase detector may be capable of determining if the difference between the determined phase difference and the fixed phase difference is equal to or more than a predetermined amount.

The device 180 may comprise a comparator which may be capable of determining if the determined phase difference is above or below the fixed phase difference by less than a predetermined amount or if the determined phase difference is above or below the fixed phase difference by the predetermined amount or more. The predetermined amount may be, for example, 1 degree, 5 degrees, 10 degrees, 45 degrees, 90 degrees, 180 degrees, 270 degrees, 360 degrees, more than 360 degrees, or any other suitable phase difference. In embodiments of the present invention, if the determined phase difference is above or below the fixed phase difference by less than a predetermined amount, the periodic signal may not be absent or may not be missing an edge. In embodiments of the present invention, if the determined phase difference is above or below the fixed phase difference by the predetermined amount or more, the periodic signal may be absent or may be missing an edge. Alternatively, a decision may be made that the periodic signal is absent or is missing an edge if the determined phase difference is above or below the fixed phase difference by the predetermined amount or less.

The device 180 may comprise an error asserter which may be capable of asserting an error signal if it is determined that the periodic signal is absent or is missing an edge. The error signal may be an in-band reset signal.

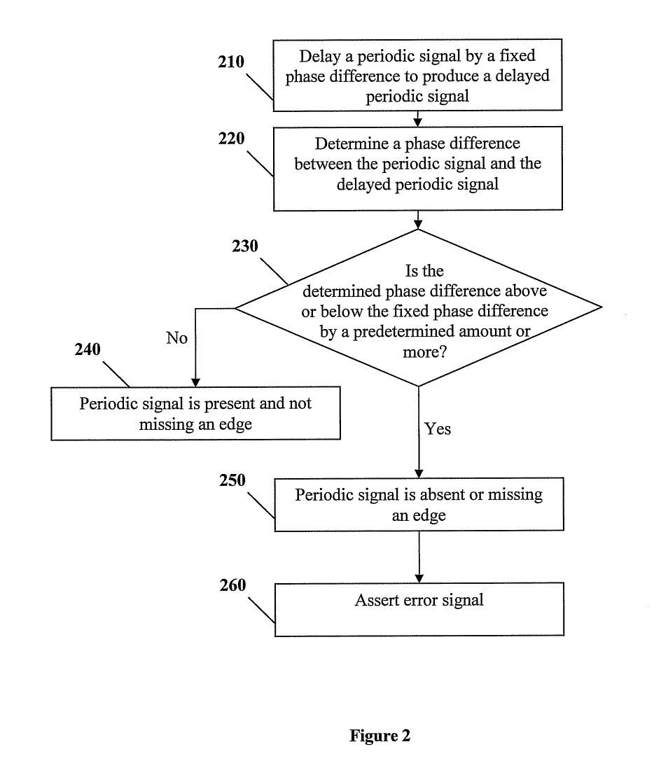

FIG. 2 shows a flowchart of a method for determining if a periodic signal is absent or if the periodic signal is missing an edge according to an embodiment of the present invention. The method may begin in operation 210 in which a device such as a delay circuit may delay a periodic signal by a fixed phase difference to produce a delayed periodic signal. The method may continue to operation 220 in which a device such as a phase detector may determine a phase difference between the periodic signal and the delayed periodic signal. The method may continue to operation 230 in which a comparator may determine if the determined phase difference is above or below the fixed phase difference by a predetermined amount or more. If the determined phase difference is above or below the fixed phase difference by a predetermined amount or more the method may continue to operation 250, otherwise the method may continue to operation 240. In operation 240 it has been determined that the periodic signal is present and is not missing an edge. The method may continue from operation 240 back to operation 210 or 220. In operation 250 it has been determined that the periodic signal is absent or is missing an edge. The method may continue from operation 250 to operation 260 in which a device such as an error asserter may assert an error signal. The method may continue from operation 250 or 260 back to operation 210 or 220.

The device 180 may comprise a delay circuit and/or a phase detector. The delay circuit and/or the phase detector may be elements of a Delay Locked Loop (DLL). A DLL may include, for example, two or more programmable delay elements chained together (together called a delay line). Each delay element has a delay that can be adjusted using digital techniques, analog techniques, or a combination of the two (i.e., each delay element is capable of producing a phase difference). The delay line of the DLL may be capable of delaying a periodic signal by a fixed phase difference to produce a delayed periodic signal. Thus, the delay circuit of device 180 may comprise a delay line of a DLL. A DLL may comprise a phase detector. The phase detector of the DLL may be capable of determining a phase difference between a periodic signal and a delayed version of the periodic signal. Thus, the phase detector of device 180 may comprise a phase detector of a DLL. For illustration purposes only, the operation of a DLL will be explained with reference to an analog implementation.

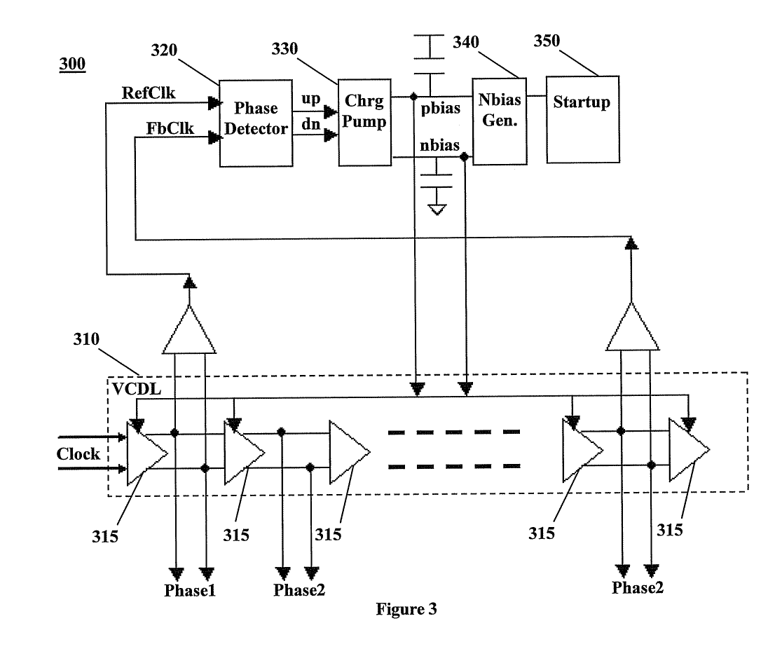

FIG. 3 shows a simplified block diagram of a DLL 300 implemented with analog circuit elements according to an embodiment of the present invention. The DLL 300 may comprise a delay line 310, a phase detector (PD) 320, a charge pump (CP) 330, a bias generator (Nbias Gen) 340, startup circuitry 350, and/or a loop filter (a capacitor is used in this example—other implementations of the loop filter are possible). The delay line 310 may be, for example, a voltage controlled delay line (VCDL). The input to the delay line may be a periodic signal. The periodic signal may be a clock signal. The delay line may have a chain of delay elements 315. The delay, or phase difference, through each delay element may be controlled by using bias voltages pbias and nbias. The output of each delay element is called a “tap”. The tap is a delayed version of the periodic signal. Thus, each tap may have a phase difference with respect to the periodic signal. The delay line may control each delay element to generate a set of taps that have an equal phase difference from one tap to the next tap in the chain. The first tap may be referred to as Phase1, the second tap as Phase2, etc. Two taps with a fixed phase difference may be input into the phase detector 320. The fixed phase difference between the two taps may be a phase difference of an integer multiple of 360 degrees or an integer multiple of one full wavelength of the periodic signal. However, other phase differences are possible. In FIG. 3, the two taps are Phase1 (RefClk) and Phase9 (FbClk).

The phase detector may determine the phase difference between the two taps. If the determined phase difference is not substantially equal to the fixed phase difference, the phase detector may pulse an up signal and/or a dn signal depending on the magnitude and sign of the difference between the determined phase difference and the fixed phase difference. The up and dn signals may be integrated by the charge pump and the loop filter capacitor to generate control voltages in the form of bias voltages pbias and nbias. A negative feedback loop may adjust the control voltages (and hence the delay of the individual delay elements) in a direction that lowers the difference between the determined phase difference and the fixed phase difference.

When the difference between the determined phase difference and the fixed phase difference is substantially zero or less than a predetermined amount, the DLL may be said to be “locked”. When the DLL is locked, the pulse widths of the up and dn signals which are output from the phase detector of the DLL may be narrow and nearly identical. Even when the DLL is locked, the up and dn signals may pulse to prevent a deadband condition in the DLL. A deadband is a region of operation in which a circuit does nothing. In the case of a DLL, a deadband may mean that the DLL is not acting to lower the difference between the determined phase difference and the fixed phase difference (and thus may not maintain its lock). To slightly adjust the phase difference between the periodic signal and the delayed periodic signal, the DLL may pulse both the up and dn signals with a slight difference in pulse length for the up signal versus the dn signal. This may be done because it is easier to create a pulse length difference than it is to create a very narrow pulse.

In an embodiment of the present invention, the two taps (Phase1 and Phase9) may be “nominally identical taps”. When the fixed phase difference is an integer multiple of 360 degrees or an integer multiple of one full wavelength of the periodic signal, the taps may be referred to as nominally identical taps. Thus, Phase1 may be the periodic signal and Phase9 may be a version of the periodic signal that is delayed by a fixed phase difference of 360 degrees or one full wavelength of the periodic signal.

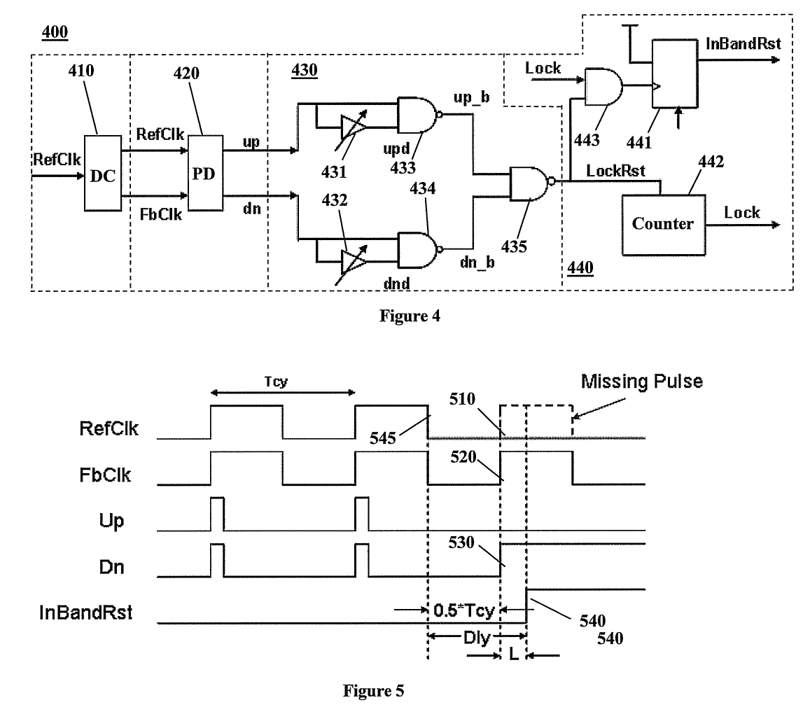

FIG. 4 shows a device 400 which may be used to detect the absence of a periodic signal or the absence of an edge of the periodic signal according to an embodiment of the present invention. The device 400 may comprise a delay circuit 410, a phase detector 420, a comparator 430, and/or an error asserter 440. The delay circuit and/or the phase detector may be, for example, elements of a DLL.

In embodiments of the present invention, the delay circuit 410 may delay a periodic signal (RefClk) by a fixed phase difference to produce a delayed periodic signal (FbClk). In embodiments of the present invention, the phase detector 420 may determine the phase difference between RefClk and FbClk. The phase detector may pulse an up signal and/or a dn signal depending on the magnitude and sign of the difference between the determined phase difference and the fixed phase difference.

In embodiments of the present invention, the comparator 430 may determine if the determined phase difference is above or below the fixed phase difference by less than a predetermined amount or if the determined phase difference is above or below the fixed phase difference by the predetermined amount or more. The comparator 430 may have a first delay buffer 431. The first delay buffer 431 may be, for example, a fixed delay buffer or a variable delay buffer. The first delay buffer 431 produces a delayed version of the up signal, upd. Thus, the upd signal will only equal the up signal after a delay. The up signal and the delayed version of the up signal, upd, may be input into a first NAND gate 433. The output of the first NAND gate 433 is the up_b signal. The up_b signal will only equal logic ‘0’ if the up signal is logic ‘1’ for longer than the delay of first delay buffer 331. The comparator 430 may have a second delay buffer 432. The second delay buffer 432 may be, for example, a fixed delay buffer or a variable delay buffer. The second delay buffer 432 produces a delayed version of the dn signal, dnd. Thus, the dnd signal will only equal the dn signal after a delay. The dn signal and the delayed version of the dn signal, dnd, may be input into a second NAND gate 434. The output of the second NAND gate 434 is the dn_b signal. The dn_b signal will only equal logic ‘0’ if the dn signal is logic ‘1’ for longer than the delay of the second delay buffer 432. Thus, the delay buffers 431 and 432 may act as low pass filters for the up and dn signals, respectively. Only if the pulse length for either the up or dn signals is long enough may up_b or dn_b, respectively, be logic ‘0’. The up_b and dn_b signals may be input to a third NAND gate 435. The output of the third NAND gate 435 is the LockRst signal. If either the up_b and dn_b signals are logic ‘0’, the LockRst signal is logic ‘1’. In other words, if the pulse length for either the up or dn signals is long enough, the LockRst signal may be logic ‘1’. When the LockRst signal is logic ‘1’, the determined phase difference is above or below the fixed phase difference by the predetermined amount or more.

In embodiments of the present invention, the predetermined amount may be a function of the delay of the first delay buffer and/or the delay of the second delay buffer. In certain embodiments of the present invention either or both of the first delay buffer and the second delay buffer may be replaced with two or more delay buffers. The delay of the delay buffers may act to set a minimum amount of time that the up or dn signals must be asserted before the LockRst signal is asserted (e.g., set to logic ‘1’). The length of time that the up or dn signals are asserted may be a function of the magnitude of the difference between the determined phase offset and the fixed phase offset. Thus, the delay of the delay buffers may be used to set the predetermined amount. The predetermined amount may be, for example, 1 degree, 5 degrees, 10 degrees, 45 degrees, 90 degrees, 180 degrees, 270 degrees, 360 degrees, more than 360 degrees, or any other suitable phase difference.

The error asserter 440 may assert an error signal if the determined phase difference is above or below the fixed phase difference by a predetermined amount or more. The error signal may be asserted when the LockRst signal is logic ‘1’. The error signal may be an in-band reset signal. The error signal may be output by a flip flop 441. The flip flop may be a metastability hardened flip flop.

The Lock signal may be logic ‘1’ when the difference between the determined phase difference and the fixed phase difference is substantially zero or less than the predetermined amount. The Lock signal may be logic ‘0’ when the difference between the determined phase difference and the fixed phase difference is not substantially zero or is equal to or greater than the predetermined amount. In embodiments of the invention in which the delay circuit and/or the phase detector are elements of a DLL, the Lock signal may reflect whether or not the DLL is currently locked.

The Lock signal and the LockRst signal may be input into an AND gate 443. The output of the AND gate may be input to the flip flop 441. The output of the flip flop is an in-band reset signal, InBandRst. When the difference between the determined phase difference and the fixed phase difference is substantially zero or less than the predetermined amount, the Lock signal may be logic ‘1’ and the LckRst signal may be logic ‘0’. Thus, the output of the AND gate 443 is logic ‘0’. When the difference between the determined phase difference and the fixed phase difference is not substantially zero or is equal to or greater than the predetermined amount, the LockRst signal may change to at logic ‘1’. When the LockRst signal is at logic ‘1’, a counter 442 may remain reset and the Lock signal may change to logic ‘0’ after a delay (e.g., a propagation delay). Thus, for the length of the delay, the Lock signal may be logic ‘1’ and the LckRst signal may be logic ‘1’. Thus, the output of the AND gate 443 is logic ‘1’ and the flip flop 441 may be triggered and the InBandRst signal may be asserted (i.e., become logic ‘1’).

When the LockRst signal changes back to logic ‘0’ (the difference between the determined phase difference and the fixed phase difference is substantially zero or less than the predetermined amount), the counter 442 counts for a predetermined amount of time and then may set the Lock signal to logic ‘1’. The predetermined amount of time may be, for example, 16, 32, 48, 64, or any other suitable number of clock cycles from a bus clock or other available clock. The InBandRst signal may be unasserted (set to logic ‘0’) by resetting the flip flop. The flip flop may be reset by the Lock signal being set to logic ‘1’ and/or by the LockRst signal being set to logic ‘0’.

FIG. 5 shows a timing diagram in which a rising edge of a periodic signal is lost according to an embodiment of the present invention. As can be seen in FIG. 5, the rising edge 510 of the periodic signal (RefClk) is absent or missing. The delay circuit 410 may delay the RefClk signal by a fixed phase difference to produce the FbClk signal. The fixed phase difference of the FbClk signal from the RefClk signal may be a full wavelength. Therefore, delayed, corresponding rising edge 520 of the FbClk signal may still exist even though rising edge 510 of the RefClk signal does not. This may cause the phase detector 420 to assert the dn signal 530. Due to the disparity between the RefClk and FbClk signals, the dn signal may be at logic ‘1’ long enough to cause the dn_b signal to become logic ‘0’ (i.e., the dn signal and the dnd signal may both be logic ‘1’). Because the dn_b signal is at logic ‘0’, the comparator 430 may cause the LockRst signal to become logic ‘1’. The change in the LockRst signal may cause the Lock signal to become logic ‘0’ after a delay. If the Lock signal was previously logic ‘1’ (i.e., in embodiments in which the delay circuit and/or the phase detector are elements of a DLL, the DLL was locked until now), LockRst changing to a logic ‘1’ may cause the in-band reset signal, InBandRst, to be asserted 540 (i.e., the flip flop 441 is triggered by the output of the AND gate 443 changing from logic ‘0’ to logic ‘1’ for the length of the delay). Tcy is the nominal wavelength of the periodic signal, L is the latency/delay in asserting the in-band reset signal 540 from the first missing rising edge of RefClk 510, and Dly is the delay between the last “good” edge 545 to the assertion of the in-band reset signal 540.

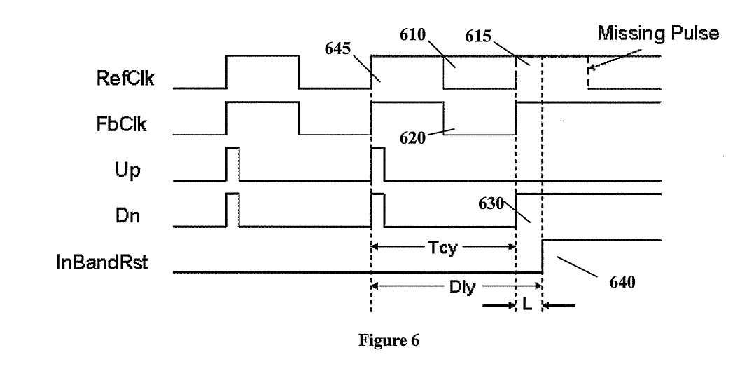

FIG. 6 shows a timing diagram in which a falling edge of a periodic signal is lost according to an embodiment of the present invention. The missing falling edge 610 of the RefClk signal and the existing delayed, corresponding falling edge of the FbClk signal 620 may cause the dn signal to be asserted 630 for long enough for the in-band reset signal, InBandRst, to be asserted 640. Thus, it is clear that embodiments of the present invention may correctly detect both missing rising edges and missing falling edges of a periodic signal. Tcy is the nominal wavelength of the periodic signal, L is the latency/delay in asserting the in-band reset signal 640 from the first missing rising edge of RefClk 615, and Dly is the delay between the last “good” edge 645 to the assertion of the in-band reset signal 640.

Among the many advantages of embodiments of the present invention are lower risk of metastability and lower latency of detection. Latency in the assertion of the in-band reset signal, InBandRst, is measured from the first missing rising edge of the RefClk signal. In an embodiment of the present invention, this latency is approximately 230 picoseconds. The latency may be dictated purely by combinational logic and may be independent of the operating frequency of the transmitted clock signal.

As mentioned previously, in embodiments of the present invention, the delay circuit may include a DLL. It should be noted that although a specific type of DLL is shown in FIG. 3 and discussed with reference to embodiments of the present invention, the invention is not limited to this implementation of a DLL. Embodiments of the present invention may be combined with a digital DLL, an analog DLL, a combination digital and analog DLL, or other suitable components. The DLL may have any number of delay elements. The DLL may use differential signaling, or single-ended signaling. Additionally, although a DLL is discussed with reference to embodiments of the present invention, the invention is not limited to a DLL. Any circuit which can detect phase differences between a periodic signal and a delayed version of the periodic signal may be operable in embodiments of the present invention. A DLL is discussed because this circuit element typically already exists in systems that would benefit from embodiments of the present invention.

It should also be noted that although the comparator and the error asserter are shown as having specific logic circuits in FIG. 4, embodiments of the present invention embrace all logic circuits that perform the same function. As those who are skilled in the art will readily recognize, there are many combinations of circuit elements that can be used to accomplish the same end result that is shown in FIG. 4. Embodiments of the present invention embrace these various combinations that are usable to determine a difference between a fixed phase difference and a determined phase difference and assert an error signal if the difference is equal to or above a predetermined amount. Further, while certain signals are given certain names, other names and other signals may be used.

The foregoing description of the embodiments of the present invention has been presented for the purposes of illustration and description. It is not intended to be exhaustive or to limit the invention to the precise form disclosed. It should be appreciated by persons skilled in the art that many modifications, variations, substitutions, changes, and equivalents are possible in light of the above teaching. Therefore, it is to be understood that the appended claims are intended to cover all such modifications and changes as fall within the true spirit of the present invention.

What is claimed is:

1. A method comprising:
delaying a periodic signal by a fixed phase difference to produce a delayed periodic signal;
determining a phase difference between said periodic signal and said delayed periodic signal;
comparing said determined phase difference to said fixed phase difference, wherein if said determined phase difference is above or below said fixed phase difference by less than a predetermined amount said periodic signal is not missing an edge, and wherein if said determined phase difference is above or below said fixed phase difference by said predetermined amount or more said periodic signal is missing said edge; and
asserting an error signal if said periodic signal is missing said edge.

2. The method of claim 1, wherein said fixed phase difference comprises a full wavelength of said periodic signal.

3. The method of claim 1, wherein said delayed periodic signal is produced by a delay line of a Delay Locked Loop.

4. The method of claim 1, wherein said determined phase difference is determined by a phase detector of a Delay Locked Loop.

5. The method of claim 1, wherein said error signal comprises an in-band reset signal.

6. The method of claim 1, wherein said periodic signal comprises a transmitted clock signal in a forwarded clock architecture.

7. A device comprising:
a delay circuit to delay a periodic signal by a fixed phase difference to produce a delayed periodic signal;
a phase detector to determine a phase difference between said periodic signal and said delayed periodic signal;
a comparator to compare said determined phase difference to said fixed predetermined phase difference, wherein if said determined phase difference is above or below said fixed phase difference by less than a predetermined amount said periodic signal is not missing an edge, and wherein if said determined phase difference is above or below said fixed phase difference by said predetermined amount or more said periodic signal is missing said edge; and
an error asserter to assert an error signal if said periodic signal is missing said edge

8. The device of claim 7, wherein said fixed phase difference comprises a full wavelength of said periodic signal.

9. The device of claim 7, wherein said delay circuit comprises a delay line of a Delay Locked Loop.

10. The device of claim 7, wherein said phase detector comprises a phase detector of a Delay Locked Loop.

11. The device of claim 7, wherein said error signal comprises an in-band reset signal.

12. The device of claim 7, wherein said periodic signal comprises a transmitted clock signal in a forwarded clock architecture.
